(19) United States
(12) Patent Application Publication
(10) Pub. No.: US 2011/0241112 A1
(43) Pub. Date: Oct. 6, 2011

(54) LDMOS Device with P-Body for Reduced Capacitance

(76) Inventor: Marco A. Zuniga, Palo Alto, CA (US)

(21) Appl. No.: 12/752,073

(22) Filed: Mar. 31, 2010

(51) Int. Cl. H01L 29/78; H01L 21/336

(52) U.S. Cl. 257/343; 438/286; 257/E29.261; 257/E21.417

(57) ABSTRACT

A transistor includes an n-well implanted in a substrate, a source region including a p-body region, a n+ region and a p+ region in the p-body region, a drain region comprising a n+ region, and a gate between the source region and the drain region. The p-body region includes a first implant region having a first depth, a first lateral spread and a first concentration of a p-type impurity, and a second implant region having a second depth, a second lateral spread and a second concentration of the p-type impurity. The second depth is less than the first depth, the second lateral spread is greater than the first lateral spread and the second concentration is greater than the first concentration. The p+ region and n+ region abut the second implant region.

### TECHNICAL FIELD

The following disclosure relates to semiconductor devices, and more particularly to a lateral diffused MOSFET (LDMOS) device.

### BACKGROUND

Voltage regulators, such as DC to DC converters, are used to provide stable voltage sources for electronic systems. Efficient DC to DC converters are particularly needed for battery management in low power devices, such as laptop notebooks and cellular phones. Switching voltage regulators (or simply “switching regulators”) are known to be an efficient type of DC to DC converter. A switching regulator generates an output voltage by converting an input DC voltage into a high frequency voltage, and filtering the high frequency input voltage to generate the output DC voltage. Specifically, the switching regulator includes a switch for alternately coupling and decoupling an input DC voltage source, such as a battery, to a load, such as an integrated circuit. An output filter, typically including an inductor and a capacitor, is coupled between the input voltage source and the load to filter the output of the switch and thus provide the output DC voltage. A controller, such as a pulse width modulator or a pulse frequency modulator, controls the switch to maintain a substantially constant output DC voltage.

Laterally diffused metal oxide semiconductor (LDMOS) transistors are used in switching regulators as a result of their low specific on-resistance and high drain to source breakdown voltage.

### SUMMARY

In one aspect, a transistor includes an n-well implanted in a substrate, a source region including a p-body region, a n+ region and a p+ region in the p-body region, a drain region comprising a n+ region, and a gate between the source region and the drain region. The p-body region includes a first implant region having a first depth, a first lateral spread and a first concentration of a p-type impurity, and a second implant region having a second depth, a second lateral spread and a second concentration of the p-type impurity. The second depth is less than the first depth, the second lateral spread is greater than the first lateral spread and the second concentration is greater than the first concentration. The p+ region and n+ region abut the second implant region.

Implementations may include one or more of the following features. The p-body region may be configured to lower a capacitance between the drain region and the source region below a pre-determined value. The p-body region may be configured to lower a capacitance between the drain region and the source region by at least 30%. The second concentration may be at least twice the first concentration. The first concentration may be in the range of 5×1012 to 1.1×1013. The first depth may be about 0.5 um deeper than the second depth. The first depth may be in the range of 0.5 to 1 um, and the second depth may be in the range of 1 to 1.5 um. The second implant region may extend laterally below the gate, e.g., by less than about 0.1 um. An edge of the first implant region may be laterally aligned with a source-side edge of the gate. The first implant region may extend laterally below the gate and the second implant region may extends laterally below the gate farther than the first implant region. The first implant region may extends laterally below the gate by about 0.2 to 0.25 um. The first implant region and the second implant region may be configured such that a potential gradient between the gate and drain is less steep than a potential gradient of a transistor having only the second implant region. The first implant region and the second implant region may be configured such that a drain to source capacitance of the transistor is at least 15% lower than a capacitance of a transistor having only the second implant region. The gate may include a first region with a first oxide layer with a first thickness and a second region with a second oxide layer with a different second thickness. The first thickness may be greater than the second thickness and the first region may be closer to the drain than the second region. The gate may be a stepped gate and the first region may abut the second region. The gate may be a dual gate and the first region may be a pre-determined non-zero distance from the second region. A n-doped shallow drain may be implanted in the drain region.

In another aspect, a method of fabricating a transistor exhibiting reduced capacitive losses includes implanting, into a surface of the substrate, a n-well region, forming a gate oxide between a source region and a drain region of the transistor, covering the gate oxide with a conductive material to form a gate of the transistor, implanting, into the source region of the transistor, a p-body region, implanting, into the source region of the transistor, a n+ region and a p+ region, in a second implant region of the p-body region, and implanting, into the drain region of the transistor, a n+ region. Implanting the p-body region includes implanting a first implant region using a first implant beam having a first energy and a first angle with respect to a normal to the first surface, such that the first implant region has a first depth, a first lateral spread and a first concentration of the second impurity, and implanting a second implant region with a second implant beam having a second energy and a second angle with respect to the normal to the first surface, such that the second implant region has a second depth, a second lateral spread and a second concentration of the second impurity, wherein the second angle is greater than the first angle, the second depth is less than the first depth, the second energy is less than the first energy, the second lateral spread is greater than the first lateral spread and the second concentration is greater than the first concentration.

In another aspect, a transistor includes an n-well implanted in a substrate, a source region including a p-body region in the n-well, and a n+ region and a p+ region in the p-body region, a drain region including a n+ region, and a dual gate between the source region and the drain region. The dual gate includes a first gate on a side closer to the source region and a second gate on a side closer to the drain region, the first gate separated from the second gate by a pre-determined distance sufficient that a capacitance between the gate and the drain is at least 15% lower than a capacitance of a transistor of the same unit cell size and configuration excepting that the first gate and second gate abut.

Implementations may include one or more of the following features. The pre-determined distance may be less than 0.5 um. A capacitance between the gate and the drain may be about 50% of overall drain capacitance and may be at least 15% lower than the capacitance of the transistor of the same unit cell size and configuration excepting that the first gate and gate abut. The first gate may include a first gate oxide layer, and the second gate may include a second oxide gate layer that is thicker than the first gate oxide layer. The first gate oxide layer may have a first thickness of less than about 100 Å, and the second gate oxide layer may have a second thickness of at least five times the first thickness. The first gate oxide may layer partially overlaps the first n+ region and the p-body region. The second gate oxide layer may partially overlaps the second n+ region and the n-doped shallow drain. The p-body region may include a first implant region having a first depth, a first lateral spread and a first concentration of a p-type impurity, and a second implant region having a second depth, a second lateral spread and a second concentration of the p-type impurity. The second depth may be less than the first depth, the second lateral spread may be greater than the first lateral spread, and the second concentration may be greater than the first concentration. The p+ region and n+ region may abut the second implant region.

In another aspect, a transistor includes an n-well implanted in a substrate, a source region including a p-body region in the n-well, and a n+ region and a p+ region in the p-body region, a drain region including a n+ region, and a dual gate between the source region and the drain region. The dual gate includes a first gate on a side closer to the source region and a second gate on a side closer to the drain region, the first gate separated from the second gate by a pre-determined distance, the first gate coupled to a first electrode that is held at a first voltage or floated during an off-state of the transistor and the second gate coupled to a second electrode that is floated or held at a different, second voltage during an on-state of the transistor.

Implementations may include one or more of the following features. The first gate may be coupled to a first electrode that is held at a first voltage during an off-state of the transistor. The second gate may be coupled to a second electrode that held at a different, second voltage during an on-state of the transistor. The second gate may be coupled to a second electrode that is floated during an on-state of the transistor. The first gate may be coupled to a first electrode that is floated during an off-state of the transistor. A difference between the first voltage and the second voltage may be sufficient that a capacitance between the gate and the drain is at least 15% lower than a capacitance of a transistor of the same configuration and unit cell size in which the same voltage is applied to the first gate and second gate during the off-state. A capacitance between the gate and the drain may be about 50% of overall drain capacitance and may be 20% lower than a capacitance of a transistor of the same configuration and unit cell size in which the same voltage is applied to the first gate and second gate during the off-state. The voltage difference may be substantially in the range 0-6 volts or tristate in an off state and 0-12 volts or tristate in on state. During the off-state the first gate may be connected to ground and second voltage may be about 0-6 volts. During the off-state the first voltage may be about 0 and second voltage may be about 0-2V or tristate. The pre-determined distance may be less than 0.5 um. The first voltage, second voltage and pre-determined distance may be configured such that a capacitance between the gate and the drain is at least 25% lower than a capacitance of a transistor of the same configuration and unit cell size in which the first gate and second gate abut and operate at the same voltage. The second oxide gate layer may be thicker than the first gate oxide layer. The first gate oxide layer may have a first thickness of less than about 100 Å, and the second gate oxide layer may have a second thickness of at least five times the first thickness. The p-body region may include a first implant region having a first depth, a first lateral spread and a first concentration of a p-type impurity, and a second implant region having a second depth, a second lateral spread and a second concentration of the p-type impurity. The second depth may be less than the first depth, the second lateral spread may be greater than the first lateral spread and the second concentration may be greater than the first concentration. The p+ region and n+ region may abut the second implant region. A gate side edge of the p-body region may be self-aligned with the source-side edge of the second gate. A n-doped shallow drain may be implanted in the drain region. A gate side edge of the n-doped shallow drain may be self-aligned with the drain-side edge of the first gate.

Certain implementations may have one or more of the following advantages. The capacitive losses of an LDMOS transistor can be reduced due to a reduction of the capacitance between the gate and drain, between the drain and source, and/or between the p-body and the n-type well. The reduction in the above capacitances can lead to a reduction in the lumped capacitance of the transistor and can increase the efficiency for a given load current of any device including such transistors, e.g., of a voltage regulator. The peak efficiency of the device can also improved due to the reduction in capacitive losses.

The details of one or more embodiments are set forth in the accompanying drawings and the description below. Other features, aspects, and advantages will become apparent from the description, the drawings, and the claims.

### DESCRIPTION OF DRAWINGS

Exemplary embodiments will hereinafter be described in conjunction with the appended drawings, wherein like designations denote like elements, and wherein:

FIG. 1A is a schematic cross-sectional view of a LDMOS device;

FIG. 1B is a schematic cross-sectional view of another implementation of a LDMOS device;

FIGS. 2A-2C are schematic cross-sectional views of a dual gate LDMOS device;

FIGS. 3A-3B are diagrams depicting potential distributions in LDMOS devices;

FIG. 4 is a flowchart showing fabrication steps for a dual gate LDMOS device; and

FIG. 5 is a graph showing load current vs. efficiency characteristics of LDMOS devices;

FIG. 6 is a circuit diagram of a buck converter.

### DETAILED DESCRIPTION

Capacitive losses degrade the efficiency of a transistor. One contribution to capacitance of the transistor is capacitance between the drain and source. Without being limited to any particular theory, capacitance between the drain and source of a transistor is a function of the gradient of the voltage potential between the drain and source. By providing the transistor with a doping profile that spreads the voltage potential gradient between the drain and source, i.e., by lowering the gradient by spreading the voltage potential difference across a larger volume, it is possible to have a transistor that exhibits lower capacitive losses.

Another contribution to the capacitance of the transistor is capacitance between the gate and drain. Without being limited to any particular theory, capacitance between the gate and drain is a function of the gradient of the voltage potential between the gate electrode and drain. The capacitive losses can also be reduced by having a dual gate including a first gate closer to the source and a second independently controllable gate spaced from the first gate and closer to the drain. In particular, by having the control voltage be applied to the first portion and having the second gate at a lower a lower voltage, the voltage potential difference can be spread across a larger volume, thereby reducing capacitance between the gate and drain. In addition, assuming that the size of the dual gate is not increased relative to a standard gate, removing a portion of the gate electrode reduces its total area, thereby reducing capacitance.

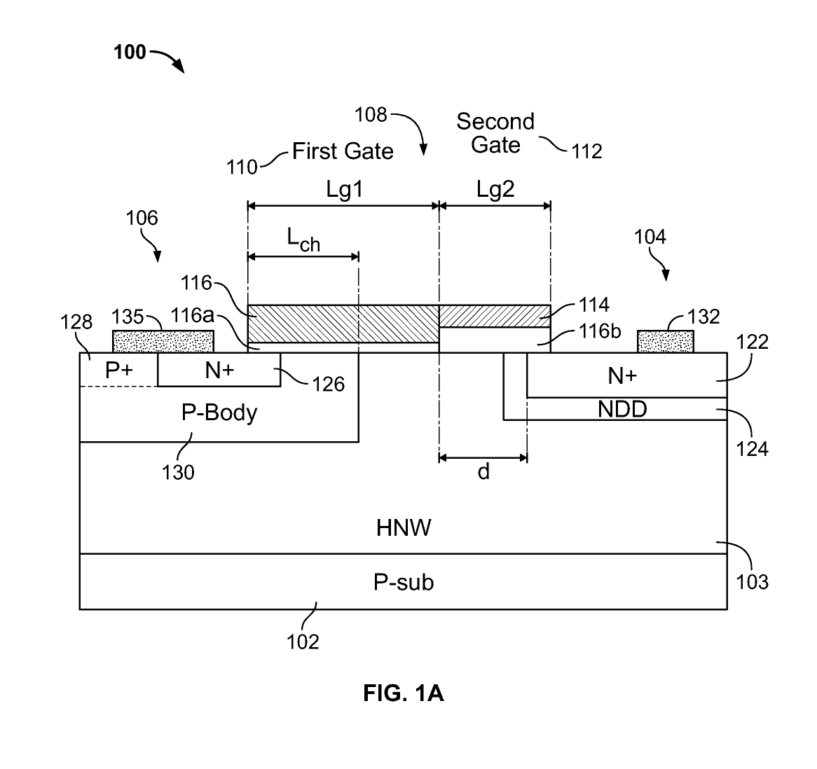

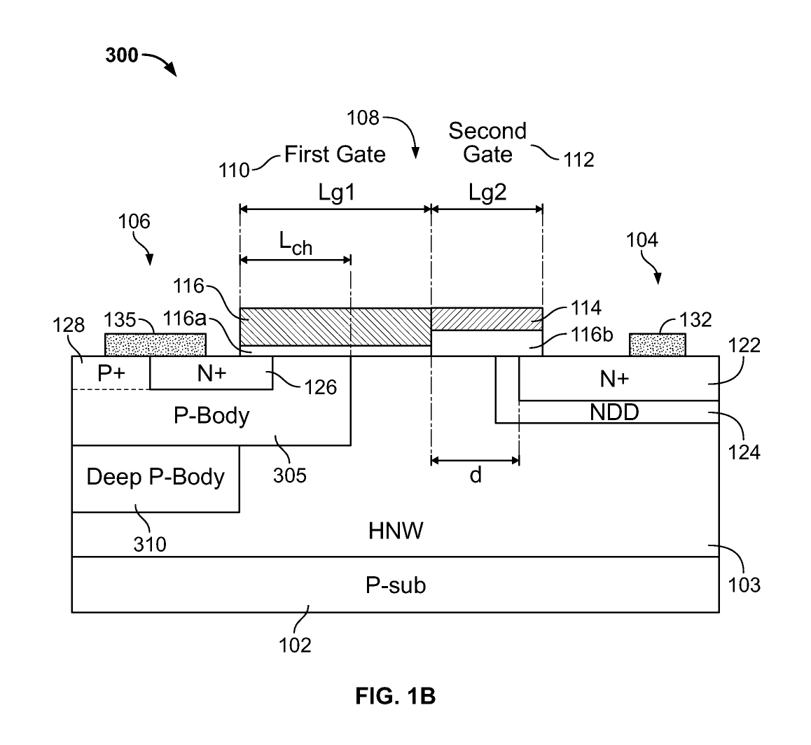

Referring to FIG. 1A, a schematic cross sectional view of a laterally diffused metal oxide semiconductor (LDMOS) transistor 100 is shown. In broad overview the transistor 100 includes a drain region 104, a source region 106 and a gate region 108. The LDMOS transistor 100 can be fabricated on a high voltage n-type well (HNW) 103 on a p-type substrate 102. The gate 108 includes a conductive layer 114, e.g., polysilicon, disposed over a dielectric layer 116, e.g., an oxide, e.g., silicon oxide. The gate can be a stepped gate that includes a first gate region 110, e.g., on the source side of the gate, and a second gate region 112, e.g., on the drain side of the gate. The first gate region 110 includes a thin oxide layer 116a, and the second gate region 112 includes a thick oxide layer 116b.

The drain region 104 may include an n-doped n+ region 122 and an n-doped shallow drain (NDD) 124. The shallow drain 124 has a lower dopant concentration than the n+ region 122, and can extend deeper than and/or further below the gate 108 than the n+ region. The n+ region 124 can be implanted in contact with, e.g., surrounded by, the shallow drain 124. A drain electrode 130 can be disposed on the substrate in electrical connection with the n+ region 122. The source region 106 includes an n-doped n+ region 126, a p-doped p+ region 128, and a p-doped P-body 130. The P-body 130 has a lower dopant concentration than the p+ region 128, and extends deeper than the n+ region 126 and p+ region 128, and further below the gate 108 than the n+ region 126. The n+ region 126 and p+ region 128 are implanted in contact with, e.g., surrounded by, the P-body 130. A source electrode 135 can be disposed on the substrate in electrical connection with the n+ region 126 and p+ region 128. Alternatively, individual contact pads can contact the n+ region 126 and p+ region 128.

In some implementations, the HNW 103 is a deep implant and is generally more lightly doped than a conventional CMOS n-well. In some implementations, the HNW 103 may have a retrograded vertical doping profile.

The basic LDMOS structure, as shown in FIG. 1A can be modified in different ways as described below. However, the LDMOS transistors discussed below remain configured in accordance with the linewidth process technologies used for fabricating the transistor 100. For example, the LDMOS transistors, including the oxide layers 116a and 116b, may be implemented using process technologies for linewidths 0.18 μm or lower.

The LDMOS transistor, as shown in FIG. 1A can be implemented as a part of a device such as a power switch, e.g., as a power switch in a voltage regulator. Such devices are often configured to handle large currents and include multiple distributed transistors connected with each other. For example, the distributed transistor can have a channel width of about 2 meters in order to provide a current capacity of about 30 ampere. In such devices, electrical connection to the n+ regions 124, n+ regions 126 and p+ regions 128 can be made by multiple contact pads in an overlying metal layer or current routing structure.

LDMOS transistors or devices including LDMOS transistors exhibit capacitive losses during operation. Without being limited to any particular theory, the resistive losses can be directly proportional to the square of the current flowing through the device whereas the switching losses can be linearly proportional to the current. Therefore, in some cases, e.g., for peak efficiency applications, the capacitive losses can be significant, and it could be useful to reduce such losses. The capacitive losses may be represented by a lumped capacitance Cₓ with respect to the drain. The lumped capacitance Cₓ may include one or more of the following: the capacitance between the gate and the drain C_{gd}, the capacitance between the drain and the source C_{ds}, and the capacitance due to the contact pads and/or the current routing structure Cₘₑₜₐₗ. The lumped capacitance may further include the capacitance between the p-body 130 and the HNW 103 C_{pb-nwl} and the capacitance between the HNW 103 and the substrate 102 C_{nwl-psub}. In some cases, the capacitance C_{ds} depends on the capacitances C_{pb-nwl} and C_{nwl-psub}. This list, however should not be considered limiting since the lumped capacitance Cₓ may also include other capacitances, including parasitic capacitances, between different points in the device. As such, the lumped capacitance Cₓ can be represented as:

Cₓ=C_{gd}+C_{ds}+C_{pb-nwl}+C_{nwl-psub}+Cₘₑₜₐₗ+C30_{misc}

where C_{misc} denotes other miscellaneous capacitances, including parasitic capacitances, that contribute to the lumped capacitance Cₓ. Therefore the lumped capacitance Cₓ can be reduced by reducing one or more of the component capacitances.

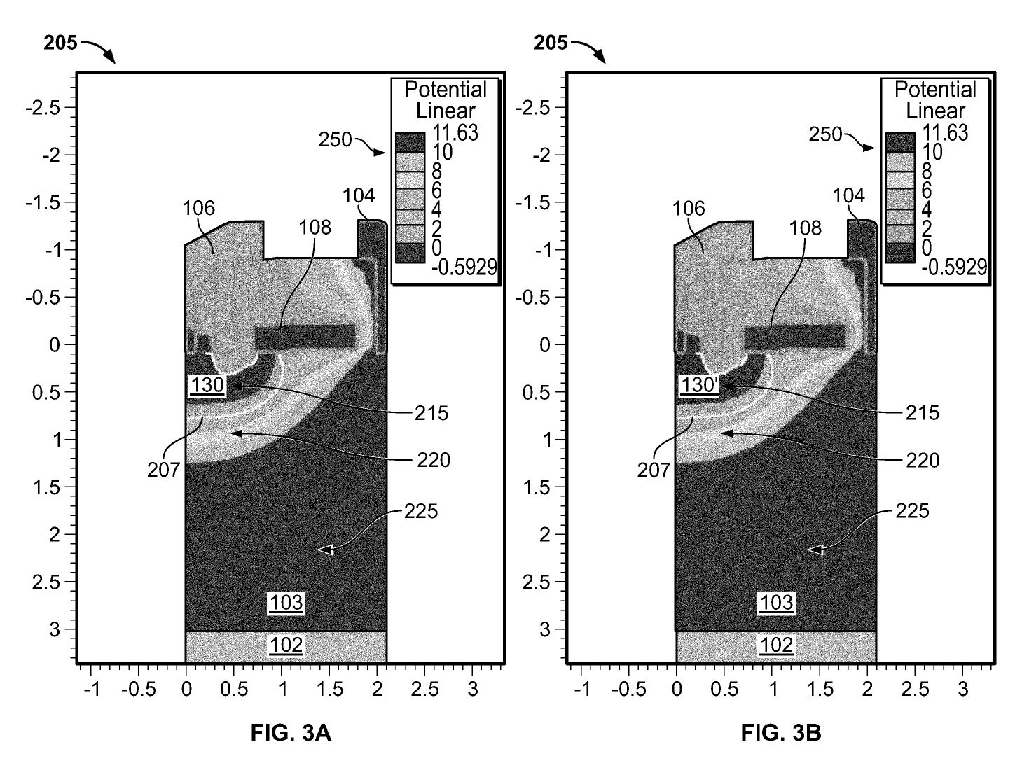

Referring now to FIG. 3A, a distribution of potential 205 across a LDMOS device such as the one described with respect to FIG. 1A is shown. The structures corresponding to the drain, source and gate are shown as 104, 106 and 108, respectively. As in FIG. 1A, the p-type substrate and the HNW are denoted as 102 and 103, respectively, while the position of the p-body is denoted as 130. The doping profile of the p-body 130 is demarcated by the line 207.

Still referring to the example in FIG. 3A, the equipotential region 225 corresponds to the highest potential in the transistor which in turn corresponds to the potential at the drain 104 and extends through most of the HNW 103. On the other hand, the equipotential region 215 corresponds to the lowest potential of the transistor at the gate 108 and the channel formed from the source 106 to the gate 108 through the p-body 130. The region 220 represents a potential gradient between the equipotential regions 215 and 225. The legend 250 shows the actual value of the potentials for this example in the equipotential regions 215, 225, and the potential gradient region 220. For example, the equipotential region 240 corresponds to a potential of 11.63 volts and the equipotential region 215 corresponds to a potential of −0.5929 volts. The potential gradient region 220 has values between these two values. Even though the graphical representation in the example in FIG. 3A shows the potential gradient region 220 to be composed of discrete regions with definite boundaries and discrete potential values, the actual potential distribution would be continuous between any two points in the device. In addition, even the equipotential regions 215 and 225 may exhibit some internal variation in their respective potentials.

The capacitance between the equipotential regions 215 and 225 and is inversely proportional to the distance between them. The capacitance between the equipotential regions may be reduced by spreading the potential difference over a larger distance. In other words, if the width of the potential gradient region 220 is increased, the capacitance between the source and the drain is decreased, leading to reduced capacitive losses. Without being limited to any particular theory, a change in the potential distribution, such as shown in FIG. 3A, leads to a change in the capacitance of the transistor and hence a change in the capacitive losses. For example, if the potential distribution is changed such that the width of the potential gradient region 220 is increased, the capacitance C_{ds} is reduced. Such an increase in the width of the potential gradient region 220 moves the equipotential regions 215 and 225 away from each other and results in a decrease in the source to drain capacitance. The increase in the width of the potential gradient also results in a decreased capacitances C_{pb-nwl} between the p-bodies and the HNW 130 and C_{nwl-psub} between the HNW 130 and the p-type substrate 102.

Referring now to FIG. 3B, an example of a potential distribution with a wider potential gradient region 220 than the one in FIG. 3A, is shown. In this example, the wider potential gradient region 220 causes the equipotential regions 215 and 225 to move away from each other, thereby reducing the capacitance between the drain and the source. The example of FIG. 3A, however, is provided purely for illustrative purposes and should not be considered limiting. For example, other contours of the equipotential regions are also within the scope of this application as long as the potential gradient region 220 is wider between the equipotential regions.

In some implementations, selection of the spreading of the potential distribution can be based on one or more constraints. For example, it can be desirable to leave a particular portion of a doping profile unchanged while altering the shape in other portions. The doping profile 209 of the p-body in FIG. 32B is an example of such a constrained profile. The doping profile 209 is configured such that the portion of the profile 209 near the gate 108 is substantially similar to a corresponding portion in the profile 207, while the portion away from the gate 108 is wider than the corresponding portion of the profile 207. This may be due to an objective to keep the length near the gate similar to the example in FIG. 3A.

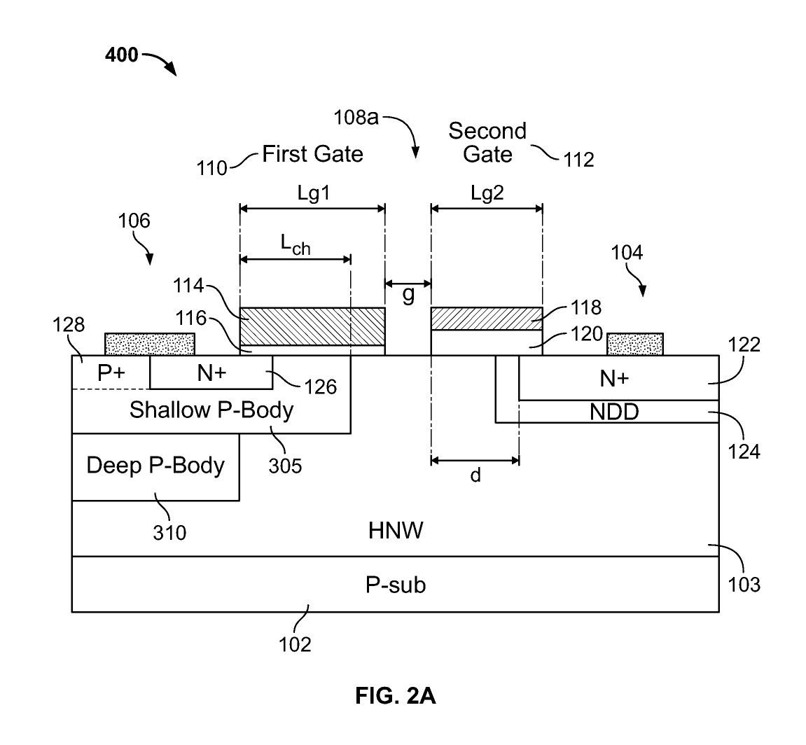

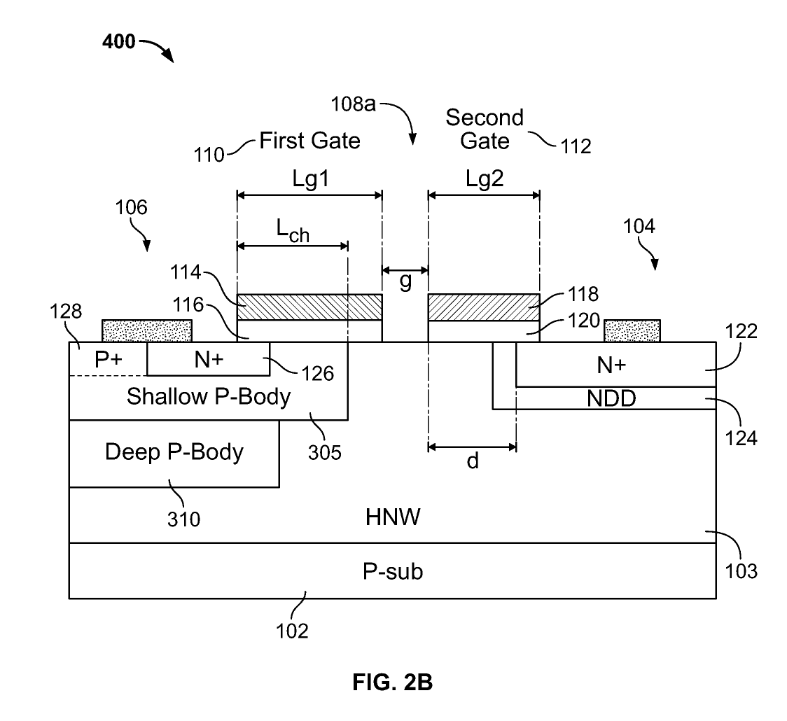

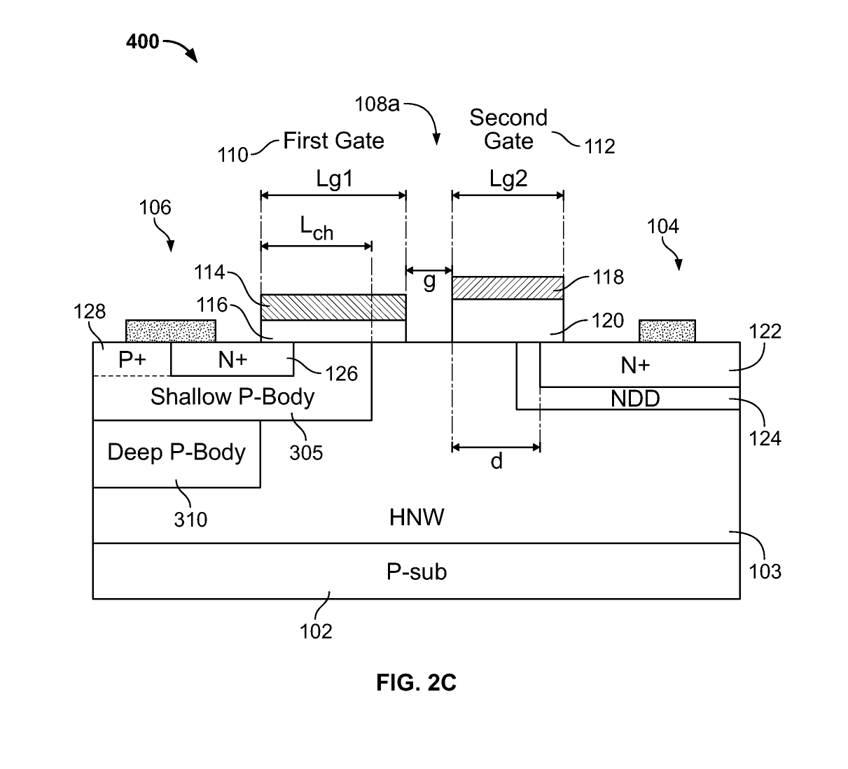

A simplified schematic of an implementation of the transistor 300 to provide the increased width of the potential gradient region 220, e.g., a potential distribution 210 shown in FIG. 3B, is illustrated in FIG. 1B. The transistor 300 can be substantially similar to the transistor 100 described with respect to FIG. 1A. However, the transistor 300 can have both a shallow and wide shallow p-body 305 and a deep p-body 310. The deep p-body 310 is deeper in the sense that it is below the shallow p-body 305 and farther from the substrate surface. The first and second p-bodies may be configured to achieve the potential distribution 210 within the transistor 300. In such cases, the width or lateral spread of the shallow p-body 305 is greater than the width or lateral spread of the deep p-body 310. In some implementations, the lateral spread of the shallow p-body 305 may extend below the gate 108. The edge of the deep p-body 310 can be aligned with the source-side edge of the gate 108 (as shown in FIG. 1B), or the deep p-body 310 can extend below the gate 108 but not as far as the shallow p-body 305 (as shown in FIG. 2B).

In some implementations the dopant concentration in the first and second p-bodies may be substantially different from each other. For example, the shallow p-body 305 has a higher concentration of a dopant while the deep p-body 310 has a lower concentration of the dopant compared to the shallow p-body 305. In some implementations, different dopant materials may be used for doping the shallow p-body 305 and the deep p-body 310, respectively. Of course, the dopant materials used for the shallow p-body 305 and the deep p-body 310 will both provide p-type doping. For example, the shallow p-body 305 can be implanted to a depth from 0.5 um to 1.0 um and at a concentration from 1×10¹³ to 8×10¹³. For example, the deep p-body 310 can be implanted to a depth greater than the shallow p-body from 0.8 um to 1.5 um, and at a concentration from 5×10¹²-1.2×10¹³. Dopant concentrations are expressed as part of the implant step, i.e., in particle flux per square centimeter.

Table 1 below shows the potential improvements associated with the modified implant procedure.

TABLE 1

| LS | Normalized | Normalized | Normalized | Normalized |
|---|---|---|---|---|
| device | Cdg | Cpn-nwl | Cnwl-psub | Total |
| 0.35 um | 0.53 | 0.33 | 0.14 | 1 |
| LD2/3 | | | | |
| 0.18 um | 0.28 | 0.28 | 0.14 | 0.71 |
| LD4 | | | | |
| % change | 47% | 21% | 0% | 30% |

In sum, approximately a 30% reduction in Cx capacitance can be possible from device structure optimization.

Even though the example in FIG. 1B shows only two different p-body regions 305 and 310, a greater number of such regions may be used. For example, there may be a third or fourth p-body region below the deep p-body region 310. The dopant concentrations in the multiple p-body regions may be varied as needed to achieve the objective of a lower capacitance while keeping the conductance of the device unchanged. For example, in some implementations, the capacitance of the device may be reduced by about 20% without any change in the resistance.

The multiple p-body regions, including the first and second p-bodies 305 and 310 may have different lateral spreads. The relative distribution of two or more p-body regions may be configured to achieve a desired potential distribution in the device 300. For example, the relative staggering, or relative lateral spreads of the shallow p-body 305 with respect to the deep p-body 310 may be configured depending upon the shape of the desired doping profile 209.

In some implementations, the boundaries between the two or more p-body regions, such as between the shallow p-body 305 and the deep p-body 310, may not be clearly defined. For example, if the shallow p-body 305 and the deep p-body 310 are defined with respect to their relative dopant concentrations, such concentration can gradually change from the shallow p-body 305 to the deep p-body 310.

In some implementations, the gate region 108 can include a stepped gate structure with the oxide layer 116b in the first gate region 110 closer to the drain being thicker than oxide layer 116b in the second gate region 112 closer to the source. The thinner oxide layer 116a permits the device 100 to be controlled by a lower gate voltage relative to a device or transistor having a controlled gate with a thicker oxide layer. In some implementations, the thickness of the oxide layer 116b may be made more than the thickness of the oxide layer 116a to achieve a desired breakdown voltage characteristic at the drain 104. For example, the thin oxide layer 116a can be less than 100 \acute{Å} thick, such as less than 40 \acute{Å} thick, for example 35 \acute{Å}. In contrast, the thick oxide layer 116b can be at least five times as thick as the thin oxide layer 116a, such as at least 10 times as thick, for example between 200 \acute{Å} and 800 \acute{Å} thick.

In some implementations, the dimensions of one or more of the first gate region 110 and the second gate region 112 may be configured to control certain characteristics. For example, the length Lg1 of the first gate region 110 may be configured to control channel conductance, the length Lg2 of the second gate region 112 may be configured to control breakdown voltage, and the total length Lg1+Lg2 may be configured to control the safe operating area (SOA). The channel length L_{ch} affects parameters such as the resistance and operating characteristics of the transistor 300 and may be configured to control such parameters.

The transistor 300 includes p-doped and n-doped regions residing adjacent to each other. Therefore, the transistor 300 may be viewed as if it includes an intrinsic body diode between the source and the drain. By varying the thickness of the oxide layer 116, and/or reducing the concentration of the p-body, the turn-on voltage (Vₜ) of the gate can be configured to be less than the turn-on voltage (V_{be}) of the intrinsic body diode. For example, the turn-on voltage of the gate can be less than 0.6V. When Vₜ is less than V_{be}, the transistor can enter third-quadrant conduction, causing current to travel through the transistor instead of the body diode.

The oxide layer 116, in combination with the shallow p-body 305 can affect the turn-on voltage (Vₜ) of the gate. For example, as the oxide layer 116 is made thinner, the turn-on voltage will be reduced. Further, the lower the concentration of dopant in the shallow p-body 305, the lower the turn-on voltage. The concentration of the p-body cannot be too low, however, because the channel length L_{ch} can become too short for the device to work. This is due to the fact that the channel is formed from scatter of a polysilicon mask on the source side. The concentration of the shallow p-body dictates how far below the polysilicon mask the dopant will scatter and form a channel.

The drain region 104 may include an n doped n+ region 122 and an n-doped shallow drain (NDD) 124. In some implementations, the n+ region 122 has an offset spacing (d) with respect to first gate region 110 and is self aligned with respect to the drain-side edge of the second gate region 112. A size of the second gate region 112 can be used to control the length of the offset spacing (d). In an implementation where the NDD 124 is self-aligned with respect to the second gate region 112, the NDD 124 does not completely extend underneath the second gate region 112. In some implementations, the NDD 124 is self-aligned with respect to the drain-side edge of the first gate region 110. In such implementations, the NDD 124 can extend completely under the second gate region 112. In some implementations, the NDD 124 is not self-aligned with respect to the gate.

The source region 106 may include an n doped n+ region 126, a p doped p+ region 128, and a p doped P-body 130. Each of the n+ region 126, p+ region 128, P-body 130, HNW 103, NDD 124, and n+ region 122 are volumes composed of doped material, and each region is defined by one or more implant steps within a semiconductor manufacturing process. In one implementation, each of NDD 124 and HNW 103 have a lower doping concentration than the n+ region 122. However, portions at which these volumes overlap have a higher doping concentration than the individual volumes separately. For example, a portion that contains the overlapping volumes of the n+ region 122, NDD 124, and HNW 103 has the highest doping concentration of all the overlapping volume portions. Likewise, the n+ region 126, p+ region 128, and P-body 130 in the source region 106 are volumes composed of doped material. Concentration, as used in this document, refers to the density of holes and electrons within a given volume and not the density of the material which is the source of the holes or electrons.

Although the transistor discussed above has a stepped gate, in some implementations, a dual gate structure can be beneficial. Returning to FIG. 1A, in some cases, an LDMOS transistor exhibits a high capacitance between the gate and the drain. For example, for the transistor 100 depicted in FIG. 1A, consider the input voltage at the gate to be V_{g} and the output voltage at the drain to be V_{d}. The gain is therefore given by:

$${A}_{gd} = \frac{{V}_{d}}{{V}_{g}} and {A}_{gd} < 1$$

Assuming the physical impedance between the gate 108 and drain 104 to be Z, the current from the gate 108 to the drain 104 is given by:

$${I}_{gd} = \frac{{V}_{g} - {V}_{d}}{Z} = \frac{{V}_{g} ( 1 - {A}_{gd} )}{Z}$$

The effective input impedance is therefore given by:

$${Z}_{eff} = \frac{{V}_{g}}{{I}_{gd}} = \frac{{V}_{g} Z}{{V}_{g} ( 1 - {A}_{gd} )} = \frac{Z}{1 - {A}_{gd}}$$

Assuming the entire impedance to be due to the capacitance C_{gd}, the physical impedance can be expressed as:

$$Z = \frac{1}{jω {C}_{gd}}$$

which gives:

$${Z}_{eff} = \frac{1}{jω {C}_{gd} ( 1 - {A}_{gd} )} = \frac{1}{jω {C}_{eff}}$$

$$where$$

$${C}_{eff} = {C}_{gd} ( 1 - {A}_{gd} )$$

where the effective capacitance C_{eff} is an example of Miller capacitance. Therefore, due to Miller effect, the effective capacitance increases when the difference between the voltages or potentials at the gate and drain is high, thereby leading to increased capacitive losses. When the first gate region 110 and the second gate region 112 are at the same voltage, e.g., using the same electrode, the resultant potential difference between the V_{g} at the gate and V_{d} at the drain increases, leading to increased capacitive losses for the reasons mentioned above.

In some implementations, discussed below with reference to FIGS. 2A-2C, the effective capacitance between the gate 108 and the drain 104 may be decreased by separating the first gate 110 and the second gate 112 by a predetermined distance. This dual gate structure discussed below can be used with or without the deep p-body describe above, although combining the dual gate structure with the deep p-body can provide a cumulative reduction in capacitance of the transistor.

In some implementations, the first gate 110 is a controlled gate and second gate 112 is a non controlled gate. A controlled gate is a gate that receives a voltage that can activate, for example, turn on or off, a corresponding device such as a transistor. In some implementations, the second gate 112 can float or be coupled to a predetermined reference voltage (not shown). In implementations where the second gate 112 gate is left floating, capacitance is effectively reduced by removing the reactive impedance allowing cgd displacement current to form while the device switches. Alternatively, both the first gate 110 and the second gate 112 can be controlled gates. In particular, by having the control voltage be applied to the first gate 110 and having the second gate 112 at a higher voltage, the voltage potential difference can be spread across a larger volume, thereby reducing capacitance between the gate and drain. In addition, assuming that the size of the dual gate is not increased relative to a standard gate, removing a portion of the gate electrode reduces its total area, thereby reducing capacitance.

Referring to FIG. 2A, an example of a LDMOS transistor 400 with a dual gate is shown and described. In some implementations, the dual gate 108a includes a first gate 110 on a side of the dual gate 108 closer to the source and a second gate 112 on a side of the dual gate 108 closer to the drain. The second gate 112 is separated by a pre-determined distance (g) from first gate 110. The first gate 110 includes a dielectric layer 116, e.g., an oxide such as silicon oxide, and a conductive layer 114, e.g., polysilicon. The second gate 112 also includes a dielectric layer 120, e.g., an oxide such as silicon oxide, and a conductive layer 118, e.g., polysilicon. The distance (g) can be controlled by a mask during fabrication of transistor 400. For example, for a 20V device, the value of ‘g’ can be around 0.3 μm.

In some implementations, the first gate 110 is a controlled gate and second gate 112 is a non controlled gate. A controlled gate is a gate that receives a voltage that can activate, for example, turn on or off, a corresponding device such as a transistor. In some implementations, the non-controlled second gate 112 can float or be coupled to a pre determined reference voltage (not shown). Alternatively, both the first gate 110 and the second gate 112 can be controlled gates.

In some implementations, the oxide layer 120 is thicker than oxide layer 116. The thinner oxide layer 116 permits the device 100 to be controlled by a lower gate voltage relative to a device or transistor having a controlled gate with a thicker oxide layer. In some implementations, the dual gate 108a allows for the transistor 400 to have a high breakdown voltage in an OFF state. The dual gate 108a also reduces the drain to source resistance R_{ds} when the transistor 400 is in an ON state. In some implementations, the first gate 110 acts as a typical transistor gate and controls an inversion layer in the channel while the second gate 112 controls the potential across a drain spacer and charge accumulation. For example, a positive voltage at the second gate increases charge accumulation, thereby reducing the resistance at the drain. The voltage applied on the second gate also determines the bias potential across the capacitance C_{gd}. In some implementations, the transistor 400 may be connected to an external circuit (not shown) that allows controlling the first gate 110 and the second gate 112 independently to maximize breakdown voltage in an OFF state and minimize R_{ds} when the transistor 400 is conducting.

The transistor 400 may be substantially similar, at least in some parts, to the transistors 100 described with respect to FIGS. 1A and 1B. For example, the transistor 400 has a drain region 104, a source region 106 and a gate region 108. The transistor 400 may be fabricated on a HNW 103 on a p-type substrate 102. The drain region 104 may include an n doped n+ region 122 and an n doped shallow drain (NDD) 124. The source region 106 may include an n doped n+ region 126 and a p doped p+ region 128.

FIG. 2A shows that the oxide layer 120 is thicker than oxide layer 116. In some implementations, the oxide layers 116 and 120 can have substantially the same thickness. This is shown in FIG. 2B. In some implementations, the combined thickness of the conductive layer 114 and the oxide layer 116 is substantially same as the combined thickness of the conductive layer 118 and the oxide layer 120. This can be achieved by polishing the conductive layer. FIG. 2C shows such an implementation. In such cases, the thickness of the conductive layers 114 and 118 may be different from or substantially same as each other.

Referring back to FIG. 2A, the thin oxide layer 116 is located underneath the first gate 110 and the thick oxide layer 120 is located under the second gate 112. The thin oxide layer 116 can be closer to the source 106 than the thick oxide layer 120 and can partially overlap the n+ region 126 and the shallow p-body 305. The thick oxide layer 120 can be closer to the drain 104 than the thin oxide layer 116 and can partially overlap the n+ region 122 and the shallow drain 124. The thick oxide layer 120 and the thin oxide layer 116 can have different thicknesses. For example, the thin oxide layer 116 can be less than 100 \acute{Å} thick, such as less than 40 \acute{Å} thick, for example 35 \acute{Å}. In contrast, the thick oxide layer 120 can be at least five times as thick as the thin oxide layer 116, such as at least 10 times as thick, for example between 200 \acute{Å} and 800 \acute{Å} thick.

For the LDMOS transistor 400, a high enough positive voltage on the first gate 110, called the turn-on voltage (Vt), will push the positive holes of the p-body away from the gate 110 to form a depletion layer. This will create a channel for electrons (n) (an “n-channel”) to flow between the source 106 and the drain 104. Varying the voltage between the first gate 110 and the substrate modulates the conductivity of the n-channel and makes it possible to control the current flow between drain and source. The thin oxide layer 116, in combination with the p-body profile, can affect the turn-on voltage (Vt) of the gate. As the thin oxide layer 116 is made thinner, the turn-on voltage will be reduced. Further, the lower the concentration of the p-body, the lower the turn-on voltage.

The transistor 400 includes p-doped and n-doped regions residing adjacent to each other. Therefore, the transistor 400 may be viewed as if it includes an intrinsic body diode between the source and the drain. By varying the thickness of the oxide layer 116, and/or reducing the concentration of the p-body, the turn-on voltage (Vₜ) of the gate can be configured to be less than the turn-on voltage (V_{be}) of the intrinsic body diode. For example, the turn-on voltage of the gate can be less than 0.6V. When Vₜ is less than V_{be}, the transistor can enter third-quadrant conduction, causing current to travel through the transistor instead of the body diode.

In some implementations, as shown in FIGS. 2A and 2C, the thickness of the oxide layer 116 may be substantially different from the oxide layer 120. For example, the thickness of the oxide layer 116 may be substantially equal to or less than 35 angstrom while the thickness of the oxide layer 120 is more than 35 angstrom. In some implementations, the thickness of the oxide 120 may be made more than the thickness of the oxide layer 116 to achieve a desired breakdown voltage characteristic at the drain 104. However, in some implementations, as shown in FIG. 2B, the thickness of the oxide layer 116 and the oxide layer 120 may be substantially the same oxide layer 120.

In some implementations, the dimensions of one or more of the first gate 110 and the second gate 112 may be configured to control certain characteristics. For example, the length of the first gate 110 Lg1 may be configured to control channel conductance, the length of the second gate Lg2 may be configured to control breakdown voltage and the total length Lg1+Lg2 may be configured to control SOA. The channel length L_{ch} affects parameters such as the resistance and operating characteristics of the transistor 400 and may be configured to control such parameters. For example, the turn-on voltage for the gate of the transistor 400 may be proportional to the channel length Lₐ. The separation g between the gates can be controlled to control capacitive losses in the transistor 400. The dimensions Lg1 and Lg2 can also be controlled depending on whether the second gate has independent voltage control or not. For example, when the second gate does not have independent voltage control, the distances g and Lg2 can be configured such that the sum of these distances is equal to the length of a second gate in a stepped structure. In some implementations, where there is a bias on the second gate, the distance g+Lg2 can be reduced to boost the intrinsic breakdown voltage. Reducing the distance g+Lg2 effectively reduces the potential difference between the gate and the drain, thereby increasing the breakdown voltage.

FIGS. 2A-2B illustrate the transistor with a deep p-body implant to provide the improved spreading of the potential gradient region and thus lower capacitance. The p-bodies 305 and 310 in the transistor 400 may be configured in substantially the same ways as described with respect to FIGS. 1B and 3B. However, in some implementations, the transistor 400 can use the dual gate structures discussed above but have only the conventional single p-body 130.

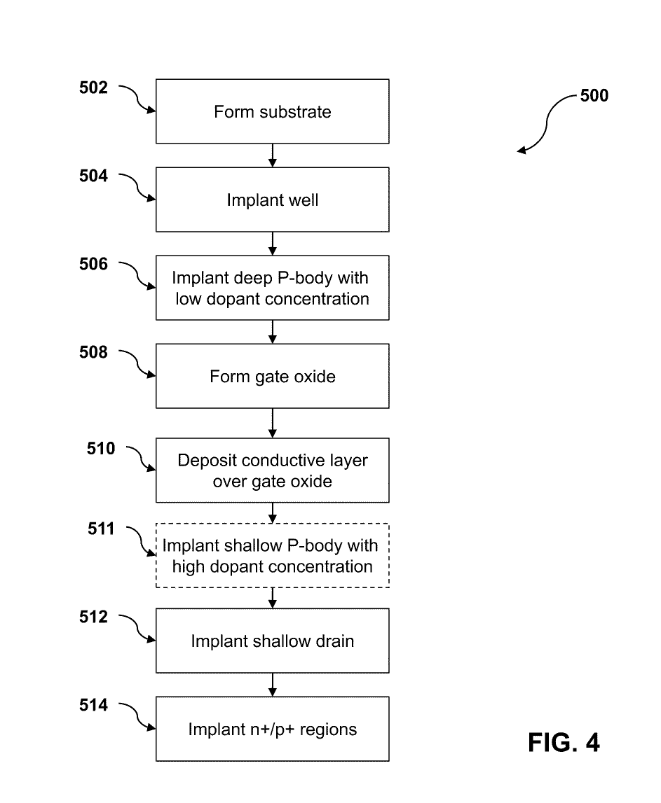

Referring now to FIG. 4, a flow diagram represents exemplary steps of a process 500 of fabricating a LDMOS transistor (e.g., device 400). The process 500 includes forming a substrate (step 502). The substrate can be a p type substrate or an n type substrate. The process 500 further includes implanting a well for the LDMOS transistor into the substrate (step 504). In some implementations, the implanted well can be an HNW 103. References to gate oxide 116 can be understood to be applicable to gate oxide portion 116a, and references to gate oxide 120 can be understood to be applicable to gate oxide portion 116b.

The process 500 also includes implanting the deep p-body 310 for the source region of the LDMOS transistor (step 506). In some implementations, the deep p-body 310 can be non self-aligned with respect to a gate, for example, the p-body may be implanted prior to formation of the gate. Alternatively, the second p-body 310 can be self-aligned with respect to a gate, i.e. the deep p-body 310 may be implanted after formation of the gate. In some implementations, the deep p-body 310 may be implanted via a low angle and high energy implant beam. The low angle and high energy of the implant beam allows the second p-body 310 to be formed deep into the HNW 103. In some implementations, the dopant concentration of the deep p-body 310 is controlled in accordance with the desired doping profile and/or desired potential distribution in the transistor. In some implementations, the deep p-body is implanted at depths from 0.8 um-1.5 um and a concentration between 5×10¹² and 1.2×10¹³, at an energy between 100-250 kev, and at an angle less than 10°.

In some implementations, the step 506 is used to implant the only p-body 130 (FIG. 1) of a transistor.

The process 500 further includes forming the gate oxides of the LDMOS transistor (step 508), e.g., by chemical vapor deposition (CVD) or thermal oxidation. In some implementations, this includes forming a first and second gate oxides 116, 120 over the HNW 103. In some implementations, this includes forming a stepped gate structure with the first and second gate oxides in contact, whereas in other implementations this includes forming a dual gate structure with the second gate oxide 120 at a predetermined distance (g) from the first gate oxide 116. In some implementations, the gate oxide 120 is thicker than the gate oxide 116 (as shown in FIGS. 4A and 4C). Alternatively, each of gate oxides 116 and 120 can have a thickness that is substantially the same (FIG. 4B). In some implementations, each of the gate oxides 116, 120 are formed at different times within a fabrication process. For example, if a shallow drain (e.g., NDD 124) is to be self aligned with respect to first gate 110, then the gate oxide 116 will be formed prior to the gate oxide 120, and the shallow drain implant step (e.g., step 512 below) will occur some time after the formation of the gate oxide 116 but before the formation of the gate oxide 120.

The process 500 further includes depositing a conductive layer, e.g., polysilicon, over the gate oxides of the LDMOS transistor (step 510), e.g., by chemical vapor deposition. In some implementations step 510 includes depositing a first conductive layer 114 over the gate oxide layer 116 and a second conductive layer 118 is deposited over the gate oxide 120 (FIGS. 4A-4C), whereas in other implementations only a single conductive layer is deposited (FIG. 3). In some implementations, the conductive layer is polished back so that portion of the conductive layer over the thin oxide layer 116 is thicker than the portion of the conductive layer over the thick oxide layer (FIGS. 3 and 4C). Alternatively, the portions of the conductive layer, e.g., each of conductive layers 114 and 118, can have a thickness that is substantially the same (FIG. 4A).

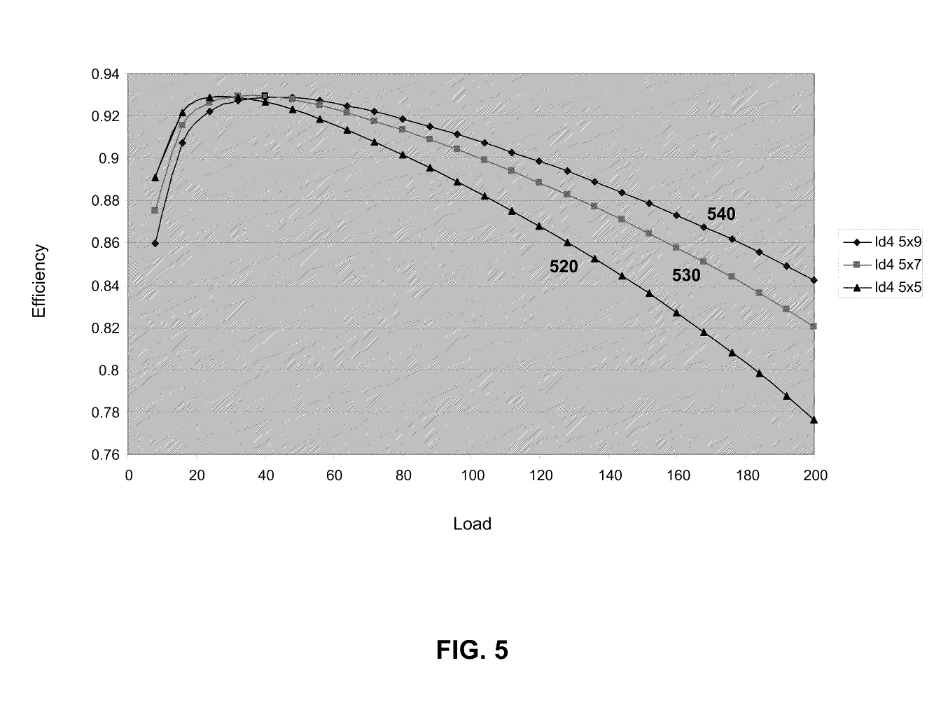

The process 500 may optionally include implanting the shallow p-body 305 (step 511). Even though the flow diagram in FIG. 5 shows step 511 to be after step 508 and 509, in alternative implementations, the shallow p-body 305 may be formed prior to forming the gate oxide. In other words, the shallow p-body 305 may or may not be self aligned with the gate. In some implementations, when the shallow p-body 305 is self-aligned with the gate, the implant is done after the conductive layer 114, such as polysilicon, is deposited because the oxide 116 may not be sufficiently thick to act as a mask for the self aligned implant. In some implementations, a high angle and low energy implant beam is used for implanting the shallow p-body 305. The lower energy of the beam allows the shallow p-body 305 to be less deep as compared to the deep p-body 310. The high angle of the beam with the vertical allows the shallow p-body 305 to have a higher lateral spread. For example, if the shallow p-body 305 is formed after the formation of the gate oxide 116, a high angle beam is used to extend the lateral spread of the shallow p-body 305 to regions under the gate oxide 116. The dopant concentration of the shallow p-body 305 is higher than that of the deep p-body 310. It should be noted that the dopant concentration and/or angle and energy of an implant beam may be varied to obtain different depth, spread and concentration in the shallow and deep p-bodies.

The process 500 also includes implanting a shallow drain at the drain region 104 of the LDMOS transistor (step 512). In the example of FIGS. 1 and 3, the shallow drain is the NDD 124. In some implementations, the NDD 124 can self aligned with respect to a gate, e.g., the gate formed by second conductive layer 118 and the gate oxide 120. Alternatively, the NDD 124 can be non-self aligned, i.e., the shallow drain can be implanted prior to the formation of both gate oxides 316, 320.

The process 500 may also include implanting the n+ regions and p+ regions of the LDMOS transistor (step 514). This may include implanting a p+ region 128 and an n+ region 126 in the source region of the LDMOS transistor. In some implementations, this further includes implanting an n+ region 122 in the drain region 104 of the LDMOS transistor. The p+ regions 128 and the n+ regions 126, 128 are highly doped (relative to NDD 124), and provide low resistivity ohmic contacts for the LDMOS transistor. The n+ region 122 may be self aligned with respect to a gate, for example the gate formed by the second conductive layer 118 and the gate oxide 120.

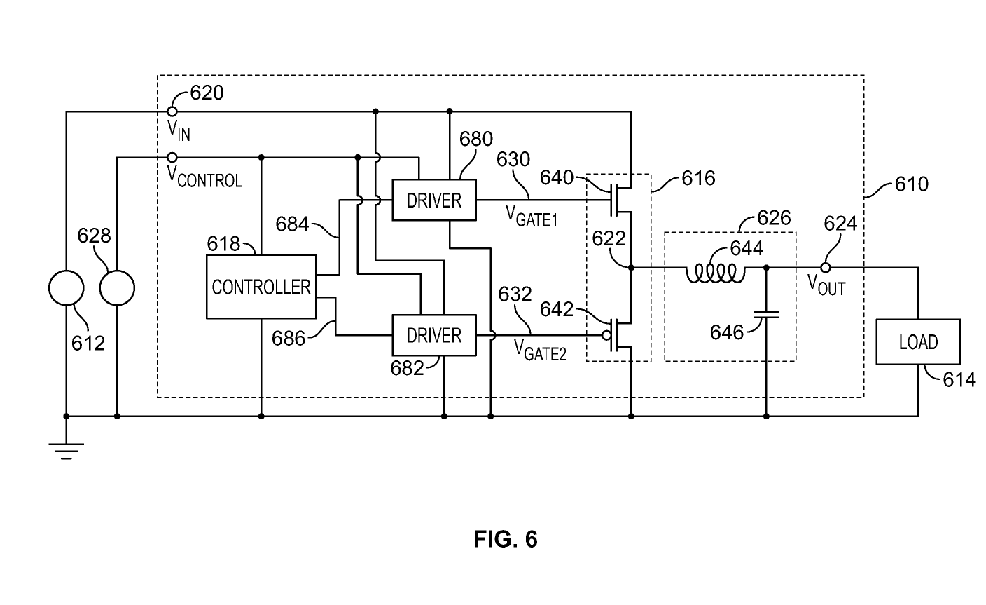

In devices such as described with respect to FIG. 4A-4C, capacitance and capacitive losses are reduced by separating the first gate 110 from the second gate 112. The peak efficiency of the transistors are thereby increased. Referring to FIG. 6, the curves 605, 610 and 615 represent the relationship between current and efficiency for different levels of packing of device sizes. Device sizes, as used here, refer to number of chip scale package (CSP) balls needed to contact the LDMOS device. For each of the curves 605, 610 and 615, the efficiency is observed to rise with the full load current for lower values of the current but decreases with the current for higher values of the current. For a given value of load current, the efficiency of LDMOS transistors may be improved by reducing capacitive losses. LDMOS transistors with multiple p-bodies, such as described above, may be used to spread the potential gradient in the transistors (and hence the devices) to reduce capacitive losses for a given load current. In some cases, it may even be desirable to have a higher efficiency at the cost of operating at a lower full load current level.

In particular, the LDMOS transistors described above may be particularly useful in devices such as a voltage converter or a switching regulator, due to desirable characteristics like high current capacity. Referring to FIG. 7, a switching regulator 710 is coupled to a first high DC input voltage source 712, such as a battery, by an input terminal 720. The switching regulator 710 is also coupled to a load 714, such as an integrated circuit, by an output terminal 724. The switching regulator 710 serves as a DC-to-DC converter between the input terminal 720 and the output terminal 724. The switching regulator 710 includes a switching circuit 716 which serves as a power switch for alternately coupling and decoupling the input terminal 720 to an intermediate terminal 722. The switching circuit 716 includes a rectifier, such as a switch or diode, coupling the intermediate terminal 722 to ground. Specifically, the switching circuit 716 may include a first transistor 740, called a high-side transistor, having a source connected to the input terminal 720 and a drain connected to the intermediate terminal 722 and a second transistor 742, called a low-side transistor, or synchronous transistor, having a source connected to ground and a drain connected to the intermediate terminal 722.

In one implementation, the first transistor 740 can be a PMOS, NMOS, or an LDMOS, and the second transistor 742 can be an LDMOS. One or both LDMOS can be implemented as described above.

The intermediate terminal 722 is coupled to the output terminal 724 by an output filter 726. The output filter 726 converts the rectangular waveform of the intermediate voltage at the intermediate terminal 722 into a substantially DC output voltage at the output terminal 724. Specifically, in a buck-converter topology, the output filter 726 includes an inductor 744 connected between the intermediate terminal 722 and the output terminal 724 and a capacitor 746 connected in parallel with the load 714. During a high-side conduction period, the first transistor is closed, and the source 712 supplies energy to the load 714 and the inductor 744 via the first transistor 740. On the other hand, during a low-side conduction period, the second transistor 742 is closed, and current flows through the second transistor 742 as energy is supplied by the inductor 744. The resulting output voltage Vₒᵤₜ is a substantially DC voltage. Although illustrated as a buck-converter, a boost-converter, buck-boost converter, or other converter topology can be used.

The switching regulator also includes a controller 718, a high-side driver 780 and a low-side driver 782 for controlling the operation of the switching circuit 716. A first control line 730 connects the high-side transistor 740 to the high-side driver 780, and a second control line 732 connects the low-side transistor 742 to the low-side driver 782. The high-side and low-side drivers are connected to the controller 718 by control lines 784 and 786, respectively. The controller 718 causes the switching circuit 716 to alternate between high-side and low-side conduction periods so as to generate an intermediate voltage Vᵢₙₜ at the intermediate terminal 722 that has a rectangular waveform. The controller 718 can also include a feedback circuit (not shown), which measures the output voltage and the current passing through the output terminal. Although the controller 718 is typically a pulse width modulator, the invention is also applicable to other modulation schemes, such as pulse frequency modulation.

A number of embodiments have been described. Nevertheless, it will be understood that various modifications may be made without departing from the spirit and scope of the invention. For example, a LDMOS transistor or device 100, 300 can be fabricated on an n-type substrate. In such an implementation, an SOI (silicon on insulator) insulation layer can be deposited (or grown) on the n-type substrate. Other embodiments are within the scope of the following claims.

What is claimed is:

1. A transistor comprising:
an n-well implanted in a substrate;
a source region including a p-body region, a n+ region and a p+ region in the p-body region, the p-body region including
a first implant region having a first depth, a first lateral spread and a first concentration of a p-type impurity, and
a second implant region having a second depth, a second lateral spread and a second concentration of the p-type impurity, wherein the second depth is less than the first depth, the second lateral spread is greater than the first lateral spread and the second concentration is greater than the first concentration, wherein the p+ region and n+ region abut the second implant region;
a drain region comprising a n+ region; and
a gate between the source region and the drain region.

2. The transistor of claim 1, wherein the p-body region is configured to lower a capacitance between the drain region and the source region below a pre-determined value.

3. The transistor of claim 2, wherein p-body region is configured to lower a capacitance between the drain region and the source region by at least 30%.

4. The transistor of claim 1, wherein the second concentration is at least twice the first concentration.

5. The transistor of claim 1, wherein the first concentration is in the range of 5×10¹² to 1.1×10¹³.

6. The transistor of claim 1, wherein the first depth is about 0.5 um deeper than the second depth.

7. The transistor of claim 1, wherein the first depth is in the range of 0.5 to 1 um and the second depth is in the range of 1 to 1.5 um.

8. The transistor of claim 1, wherein the second implant region extends laterally below the gate.

9. The transistor of claim 8, wherein the second implant region extends laterally below the gate by less than about 0.1 um.

10. The transistor of claim 8, wherein an edge of the first implant region is laterally aligned with a source-side edge of the gate.

11. The transistor of claim 8, wherein the first implant region extends laterally below the gate and the second implant region extends laterally below the gate farther than the first implant region.

12. The transistor of claim 11, wherein the first implant region extends laterally below the gate by about 0.2 to 0.25 um.

13. The transistor of claim 1, wherein the first implant region and second implant region are configured such that a potential gradient between the gate and drain is less steep than a potential gradient of a transistor having only the second implant region.

14. The transistor of claim 1, wherein the first implant region and second implant region are configured such that a drain to source capacitance of the transistor is at least 15% lower than a capacitance of a transistor having only the second implant region.

15. The transistor of claim 1, wherein the gate comprises a gate having a first region with a first oxide layer with a first thickness and a second region with a second oxide layer with a different second thickness.

16. The transistor of claim 15, wherein the first thickness is greater than the second thickness and the first region is closer to the drain than the second region.

17. The transistor of claim 16, wherein the gate is a stepped gate and the first region abuts the second region.

18. The transistor of claim 17, wherein the gate is a dual gate and the first region is pre-determined distance from the second region.

19. The transistor of claim 1, further comprising a n-doped shallow drain implanted in the drain region.

20. A method of fabricating a transistor exhibiting reduced capacitive losses, the method comprising:
implanting, into a surface of the substrate, a n-well region;
forming a gate oxide between a source region and a drain region of the transistor;
covering the gate oxide with a conductive material to form a gate of the transistor;
implanting, into the source region of the transistor, a p-body region, wherein implanting the p-body region comprises,
implanting a first implant region using a first implant beam having a first energy and a first angle with respect to a normal to the first surface, such that the first implant region has a first depth, a first lateral spread and a first concentration of the second impurity, and
implanting a second implant region with a second implant beam having a second energy and a second angle with respect to the normal to the first surface, such that the second implant region has a second depth, a second lateral spread and a second concentration of the second impurity, wherein the second angle is greater than the first angle, the second depth is less than the first depth, the second energy is less than the first energy, the second lateral spread is greater than the first lateral spread and the second concentration is greater than the first concentration;
implanting, into the source region of the transistor, a n+ region and a p+ region, in the second implant region of the p-body region; and
implanting, into the drain region of the transistor, a n+ region.
